(19) United States
(12) Patent Application Publication
(10) Pub. No.: US 2014/0035609 A1
(43) Pub. Date: Feb. 6, 2014

(54) PROBE CARD WITH SIMPLIFIED REGISTRATION STEPS AND MANUFACTURING METHOD THEREOF

(71) Applicant: JUNG-TANG HUANG, Taipei City (TW)

(72) Inventors: JUNG-TANG HUANG, TAIPEI (TW); JIAN-MING LIN, TAIPEI (TW); KUO-YU LEE, TAIPEI (TW); GAO-TING CHENG, TAIPEI (TW)

(73) Assignee: Jung-Tang Huang, Taipei City (TW)

(21) Appl. No.: 13/954,670

(22) Filed: Jul. 30, 2013

(30) Foreign Application Priority Data
Aug. 3, 2012 (TW) 101128131

(51) Int. Cl. G01R 1/073; H01L 21/50

(52) U.S. Cl. CPC G01R 1/073; H01L 21/50
USPC 324/755.01; 438/116

(57) ABSTRACT

A probe card is provided. The probe card includes a probe module and a first carrier board. The probe module has a plurality of probes. The probe module is disposed on the first carrier board. The first carrier board is at least partially light-transmitted and has a plurality of vias and a plurality of conductive fillers. The vias are filled with the conductive fillers, respectively. The probe module is electrically connected to the conductive fillers. With the first carrier board being partially light-transmitted, not only is it feasible to simplify the steps of registering the probe card and a device under test, but it is also feasible for an inspector to inspect the contact between the probe card and the device under test synchronously.

### BACKGROUND OF THE INVENTION

1. Field of the Invention

The present invention relates to a probe card and a manufacturing method thereof, and more particularly, to a probe card with simplified registration steps and a manufacturing method thereof.

2. Description of the Prior Art

In a typical wafer test procedure, to send a test signal to an integrated circuit of a device under test (DUT), it is necessary for a plurality of microprobes on a probe card to come into contact with a pad of the DUT. Afterward, the test signal is sent from a test platform to some of the probes of the probe card and forwarded to the integrated circuit electrically connected to the pad. After the test signal has been computed or processed by the integrated circuit, the test platform reads a feedback signal from the remaining probes, and then the feedback signal is analyzed by a microprocessor on the test platform to finalize the wafer test procedure.

According to the prior art, a probe card is manufactured by a semiconductor process which involves forming a plurality of microprobes on a surface of a silicon substrate and mounting a circuit chip having a microcontroller on another surface of the silicon substrate by flip-chip bonding. However, to enable the probes to be aimed at the pads on the DUT being tested by the probe card, it is necessary to take pictures of the pads on the DUT and the probes on the probe card by means of a photographic lens, calculate the distance between each of the probes and a corresponding one of the pads according to the pictures, and move the DUT with a mobile carrier platform or move the probe card with a robotic arm, so as to enable the probes to be aimed at the pads, respectively. The aforesaid process requires comparing repeatedly the pictures taken of the DUT and the probe card and thus results in relatively long registration time. Also, if the probes do not actually come into contact with the pads or the probes sever, it will be impossible for an inspector to observe directly and determine how well the probes are in contact with the pads, because the probe card and the DUT are made from a silicon substrate which is not light-transmitted.

### SUMMARY OF THE INVENTION

In view of the aforesaid drawbacks of the prior art, it is an objective of the present invention to provide a probe card conducive to a decrease in the required registration time.

Another objective of the present invention is to provide a probe card manufacturing method for manufacturing a probe card so as to enable a user to observe the contact between the probe card and a device under test (DUT) synchronously.

Another objective of the present invention is to provide a probe card manufacturing method whereby relatively short time is required for manufacturing a probe card which enables a user to observe the contact between the probe card and the DUT. The probe card of the present invention is a self-contained module, such that the probe card can test DUTs of different dimensions immediately in accordance with different via positions and the probe design.

In order to achieve the above and other objectives, the present invention provides a probe card which comprises a probe module and a first carrier board. The probe module has a plurality of probes disposed on the first carrier board. The first carrier board is at least partially light-transmitted and has a plurality of vias and a plurality of conductive fillers. The vias are filled with the conductive fillers, respectively. The probe module is electrically connected to the conductive fillers.

As regards the probe card in another embodiment of the present invention, a plurality of probe modules can be designed and built on the same carrier board so as to enable concurrent measurement of a variety of device under tests (DUTs), thereby allowing the probe card to effectuate a wafer-level test.

In an embodiment of the present invention, the first carrier board of the probe card is made of a glass or a quartz substrate. For example, the probes of the probe module are arranged in an array. The probes are made of a metal or an alloy. In another embodiment, the probes are made of carbon, a carbon compound, or a carbon alloy.

A probe card manufacturing method put forth by the present invention comprises the steps of: providing a first carrier board, wherein the first carrier board is at least partially light-transmitted; forming a plurality of vias on the first carrier board; filling the vias with a plurality of conductive fillers by a thin-film process; forming a plurality of bumps on the conductive fillers; providing a second carrier board and forming a plurality of needle-point cavities on the second carrier board by a photolithography process and an etching process; forming a plurality of probes on the needle-point cavities by an electrforming process and a planarization process; and coupling the probes to the plurality of bumps.

In conclusion, as regards a probe card put forth by the present invention, the first carrier board is at least partially light-transmitted. Hence, to perform the procedure of registration between the probe card and a device under test (DUT), it is feasible for an inspector to watch from above the probe card directly the relative position between the probe card and the DUT, and thus for an inspector to finish the registration by moving the probes or the DUT directly, thereby speeding up the registration procedure greatly. In addition, during the registration procedure, the inspector can synchronously observe and determine whether the contact between the probe card and the DUT is good to thereby ensure that subsequent test steps can be performed smoothly.

### BRIEF DESCRIPTION OF THE DRAWINGS

The above and other objectives, features, and advantages of the present invention are hereunder illustrated with preferred embodiments in conjunction with the accompanying drawings, in which:

FIG. 1A is a structural schematic view of a probe card according to the first embodiment of the present invention;

FIG. 1B is a structural schematic view of the probe card shown in FIG. 1A and having a circuit module disposed thereon;

FIG. 2 is a curve of a carrier board material against signal return loss;

FIG. 3A through FIG. 3H are schematic views of the process flow of a probe card manufacturing method according to the first embodiment of the present invention;

FIG. 4A through FIG. 4E are structural schematic views of a probe card according to the second embodiment of the present invention;

FIG. 5A through FIG. 5D are structural schematic views of a probe card according to the third embodiment of the present invention; and

FIG. 6 is a structural schematic view of a probe card according to the fourth embodiment of the present invention.

### DETAILED DESCRIPTION OF THE EMBODIMENTS

### First Embodiment

To overcome the drawbacks of the prior art, the present invention puts forth a probe card and a probe card manufacturing method. The structures and benefits of the probe card according to the first embodiment of the present invention are described below.

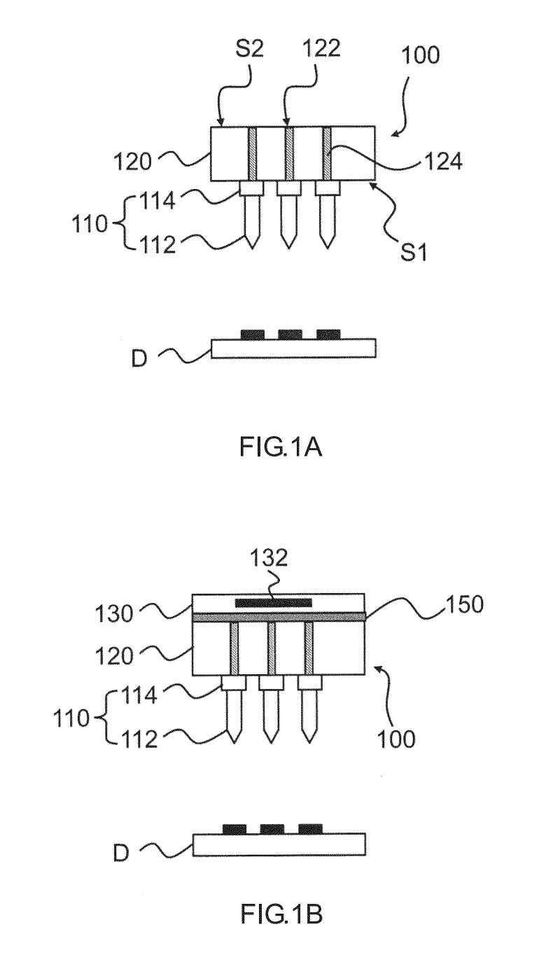

FIG. 1A, there is shown a structural schematic view of a probe card according to the first embodiment of the present invention. Referring to FIG. 1A, a probe card 100 in this embodiment comprises a probe module 110 and a first carrier board 120. The probe module 110 is disposed on the first carrier board 120 and has a plurality of probes 112. The first carrier board 120 is at least partially light-transmitted.

As regards the probe card 100 in this embodiment, the first carrier board 120 has a first surface S1 and a second surface S2 opposing the first surface S1. The probe module 110 is disposed on the first surface S1 of the first carrier board 120 and comprises the plurality of probes 112 and a plurality of bumps 114. The probes 112 are connected to the bumps 114 and arranged in an array. The probes 112 are made of a nickel-cobalt alloy. The bumps 114 are made of metallic tin. Required circuit components or modules can be disposed on the second surface S2.

The first carrier board 120 is a transparent glass substrate. The glass substrate has therein a plurality of through glass vias (TGV) 122. The vias 122 are filled with conductive fillers 124, respectively, which are made of copper. The probe module 110 is electrically connected to the conductive fillers 124 through the bumps 114.

It should be noted that the first carrier board 120 in this embodiment is a glass substrate. Due to the light permeability characteristic of the glass substrate, to perform a procedure of registration between the probe card 100 and a device under test (DUT) D, an inspector watches from above the probe card 100 the relative position between the probe card 100 and the DUT D. Hence, during the registration procedure, the inspector can directly move the probe card 100 or the DUT D and synchronously observe and determine whether the registration between the probe card 100 and the DUT D is accurate and whether the contact between the probe card 100 and the DUT D is good.

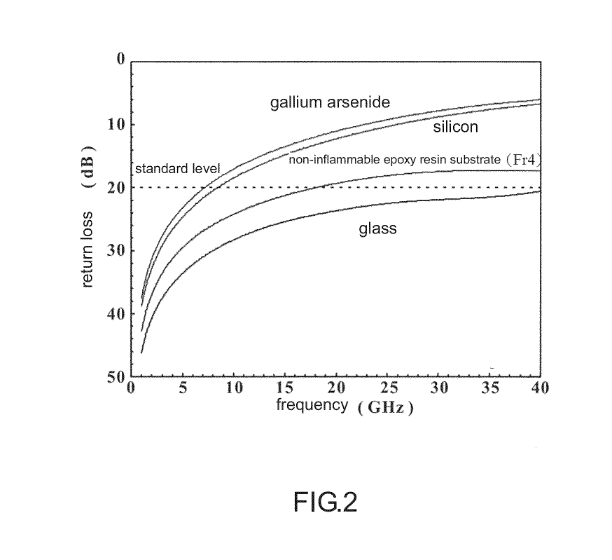

In addition to the light permeability of the glass substrate, signal return is reduced by using the glass substrate to underpin a circuit module and the probe module 110. FIG. 2 is a curve of a carrier board material against signal return loss. As revealed by the curve of FIG. 2, the glass substrate having the plurality of through glass vias (TGV) functions as a carrier board and thereby reduces signal return greatly, thus enhancing the accuracy of measurement results.

Referring to FIG. 1B, in another embodiment, given the multilayer structure of a bonding pad redistribution layer 150, a circuit module 130 can be disposed on the second surface S2. The circuit module 130 comprises a microcontroller 132 therein for controlling the probe card 100 to send a measurement signal and read a feedback signal from the DUT D. The circuit module 130, the bonding pad redistribution layer 150, the first carrier board 120, the vias 122, and the conductive fillers 124 together form a space transformation module (space transformer) to adjust the circuit layout between the circuit module 130 and the probes 112 according to a test requirement, positions of the probes, or the dimensions of the probe card, such that the whole architecture forms a smart probe card.

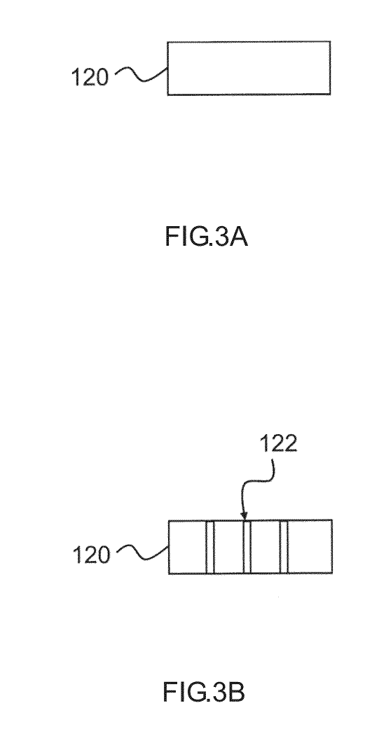

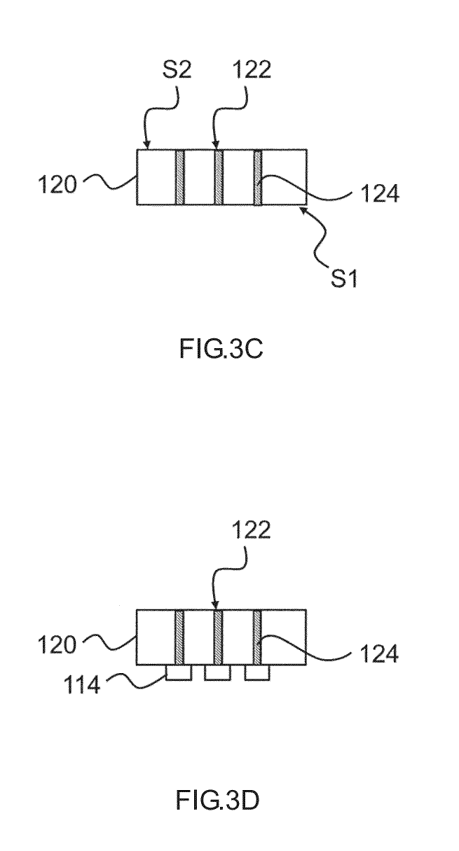

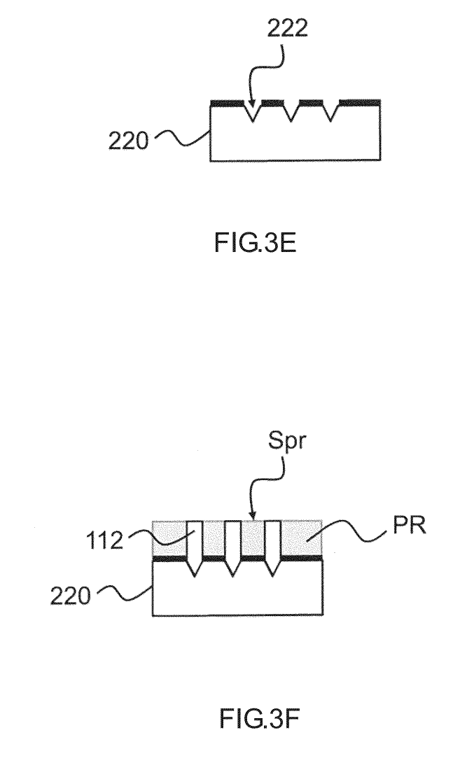

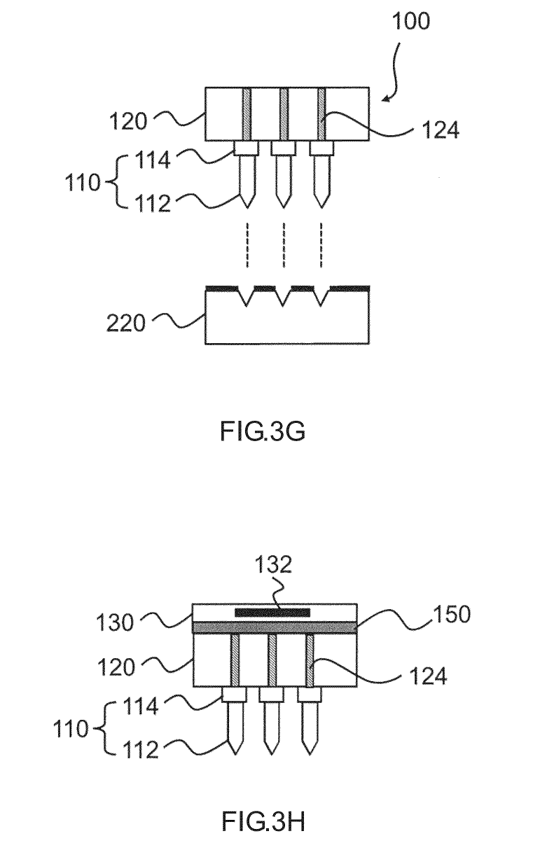

The structures and benefits of the probe card 100 in the first embodiment of the present invention are described above. A method for manufacturing the probe card 100 is described below. FIG. 3A through FIG. 3H are schematic views of the process flow of a probe card manufacturing method according to the first embodiment of the present invention. Referring to FIG. 3A , to manufacture the probe card 100, it is necessary to provide a first carrier board 120 first, and the first carrier board 120 has to be at least partially light-transmitted.

Referring to FIG. 3B, the probe card manufacturing method involves forming a plurality of vias 122 on the first carrier board 120. For example, the vias 122 are formed by piercing the first carrier board 120 by means of laser.

Referring to FIG. 3C, after a plurality of vias 122 has been formed, the vias 122 are filled with the plurality of conductive fillers 124 by a thin-film process. For example, the thin-film process includes physical vapor deposition (PVD), chemical vapor deposition (CVD), or electroplating whereby the vias 122 are filled with metallic copper. To allow the conductive fillers 124 to be flush with the vias 122, respectively, it is feasible that, upon completion of the thin-film process, a planarization process (such as chemical mechanical polishing) is carried out to remove residual metallic copper and thereby prevent the conductive fillers 124 from protruding from the first surface S1 and the second surface S2 of the first carrier board 120.

Referring to FIG. 3D, to allow the probes to be fixed in place, it is necessary to form the plurality of bumps 114 on the conductive fillers 124. Furthermore, to increase the bonding of the metallic copper and the bumps 114 thereon, a gold layer (not shown) is electroplated between the bumps 114 and the conductive fillers 124.

In another aspect, to manufacture the probes, it is necessary to provide a second carrier board 220 (see FIG. 3E) and form a plurality of needle-point cavities 222 on the second carrier board 220 by a photolithography process and an etching process. In this embodiment, the surface of the second carrier board 220 has a silicon dioxide layer, and a monocrystalline silicon substrate is beneath the silicon dioxide layer. For example, the photolithography process involves performing local exposure on a positive photoresist by means of a photomask and then removing the exposed portion of the photoresist by means of a developing solution. For example, the etching process involves etching the silicon dioxide layer with a buffer oxidation etchant (BOE) and then etching the monocrystalline silicon substrate anisotropically with potassium hydroxide (KOH) solution (using silicon dioxide as a mask) so as to form the inverted pyramid-shaped needle-point cavities 222.

Referring to FIG. 3F, upon formation of the needle-point cavities 222, the needle-point cavities 222 are filled with a nickel-cobalt alloy by an electroforming process, and then the residual nickel-cobalt alloy is removed by the planarization process (such as chemical mechanical polishing), such that the upper edge of the nickel-cobalt alloy filler does not protrude from a surface Spr of a photoresist PR, so as to finalize the formation of the plurality of probes 112.

Referring to FIG. 3G, the process flow involves removing the photoresist PR, bonding the probes 112 to the plurality of bumps 114, and removing the second carrier board 220. In doing so, the probe card 100 can be manufactured. For example, a reflow technique is applied to bonding the probes 112 to the bumps 114.

Referring to FIG. 3H, the process flow involves forming the bonding pad redistribution layer 150 on the plurality of conductive fillers 124 of the first carrier board 120 and bonding the circuit module 130 having therein the microcontroller 132 to the bonding pad redistribution layer 150. In doing so, required circuit components can be disposed on the probe card 100.

As regards the probe card manufacturing method of the present invention, since the nickel-cobalt alloy which fills the needle-point cavities 222 is processed by the planarization process (such as chemical mechanical polishing), the probes 112 manifest satisfactory coplanarity. Since a reflow technique is applied to bonding the first carrier board 120, the probe card manufacturing method of the present invention reduces the likelihood of poor contact between a device under test and the probes, as opposed to the prior art that requires soldering items together one by one.

In the above embodiments, although the probe card manufacturing method involves providing the first carrier board 120 first, forming the plurality of vias 122 on the first carrier board 120, and filling the vias 122 with the conductive fillers 124, the present invention is not restricted to the step of forming the vias 122 and filling the vias 122 with the conductive fillers 124. In another embodiment, another first carrier board having therein vias and conductive fillers is manufactured beforehand, and then bumps, probes and a circuit module are bonded to the carrier board. Therefore, it takes less time to manufacture the probe card.

### Second Embodiment

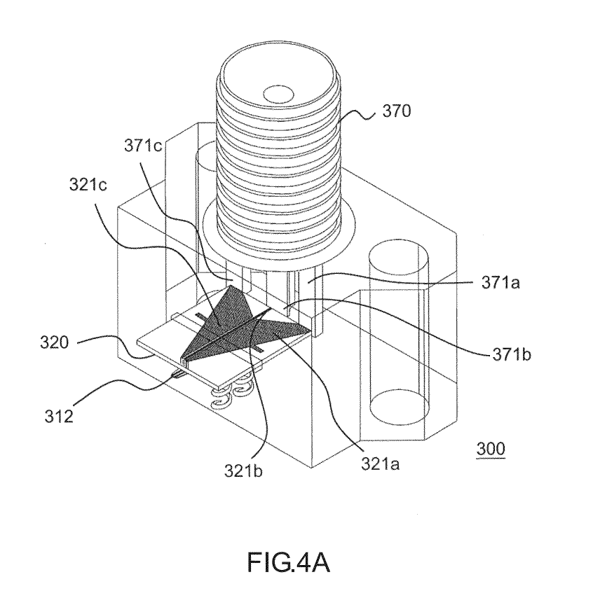

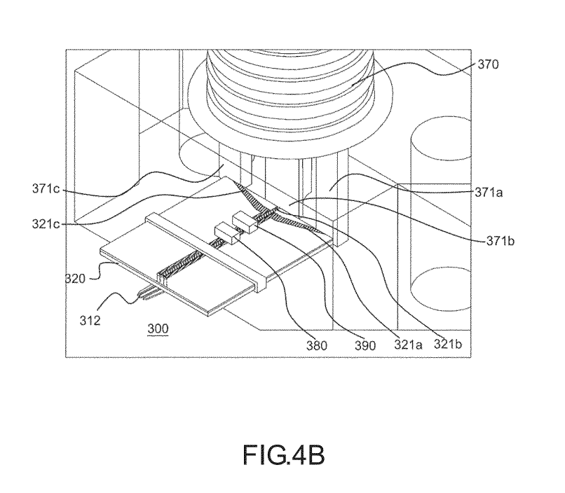

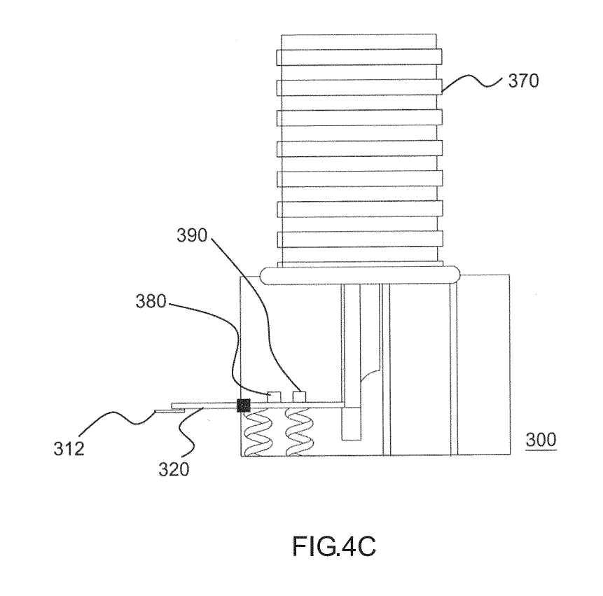

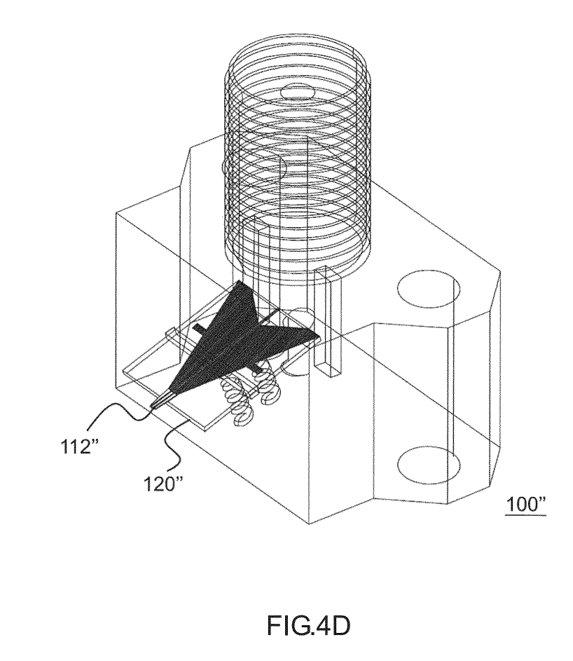

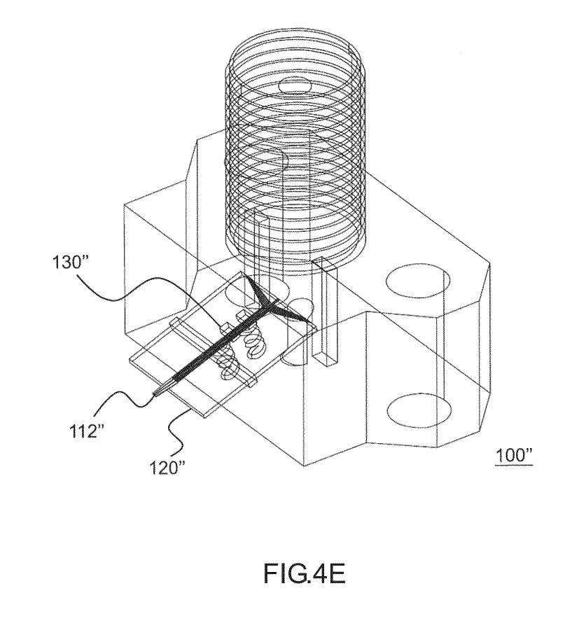

Although the present invention is characterized in that the probes 112 of the probe card 100 are perpendicular to the first carrier board 120, the present invention is not restricted to the aforesaid technical feature. FIG. 4A through FIG. 4E are structural schematic views of the probe card according to the second embodiment of the present invention. FIG. 4A is a top view of the probe card. FIG. 4B is a top view of the probe card having a circuit module thereon. FIG. 4C is a right perspective view of FIG. 4B. As regards a probe card 300 of FIG. 4A, a plurality of probes 312 is parallel to the surface of a first carrier board 320 which is at least partially transparent. Hence, the probe card 300 is applied to measuring different types of devices under test.

The conducting wires 321a , 321b, 321c are disposed on the surface of the first carrier board 320 and adapted to connect the probes 312 and a sub-miniature A connector (SMA connector) 370. The conducting wires are specially designed to achieve impedance matching. The probe card of the present invention can be coupled to a commercially available SMA connector by soldering. The conducting wires 321a, 321c are connected to the outermost probes 312, respectively. The conducting wire 321b is connected to the intermediate probes 312. Referring to FIG. 4A and FIG. 4B, the conducting wires 321a , 321b, 321c are connected to terminals 371a, 371b, 371c of the SMA connector 370, respectively. In addition, the conducting wires 321a, 321b, 321c are electrically connected to the probes 312 through the conductive fillers in the through glass vias. Referring to FIG. 4B and FIG. 4C, in this embodiment, a circuit module 380 or a match circuit component 390 is disposed on a bonding pad redistribution layer and then connected to the conducting wires to thereby form a smart probe card, thereby resulting in the same advantages as described in the first embodiment.

A probe card 100″ in FIG. 4D, FIG. 4E is similar to its counterparts in FIG. 4A, FIG. 4B, except that a probe 112″ and a circuit module 130″ of the probe card 100″ are disposed on the same side of a first carrier board 120″.

The advantages of the probe cards 300, 100″ in the second embodiment are identical to that in the first embodiment and thus are not reiterated for the sake of brevity.

### Third Embodiment

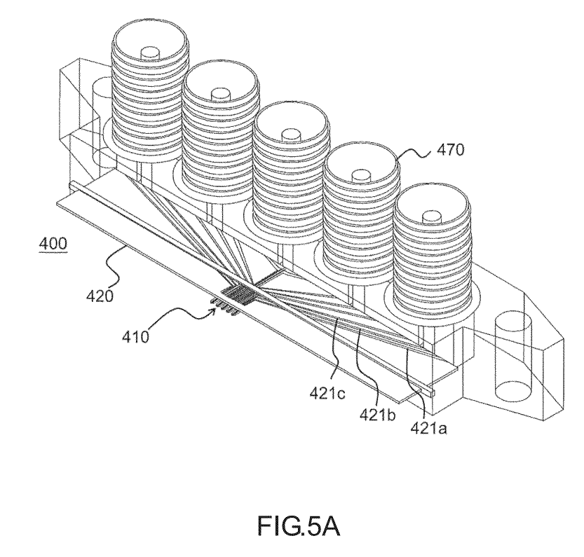

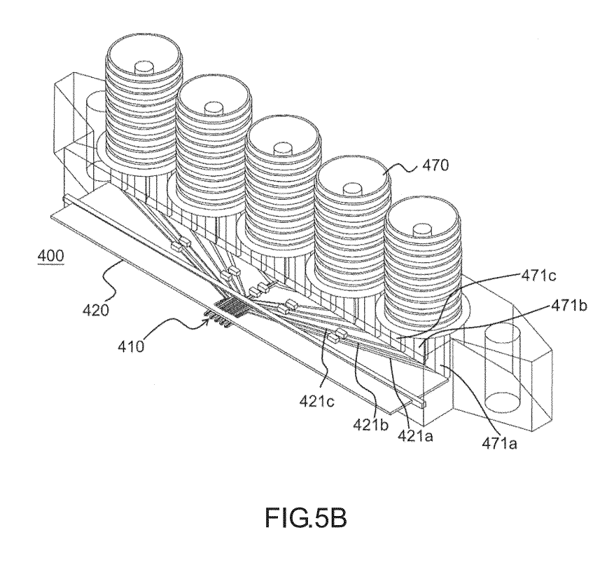

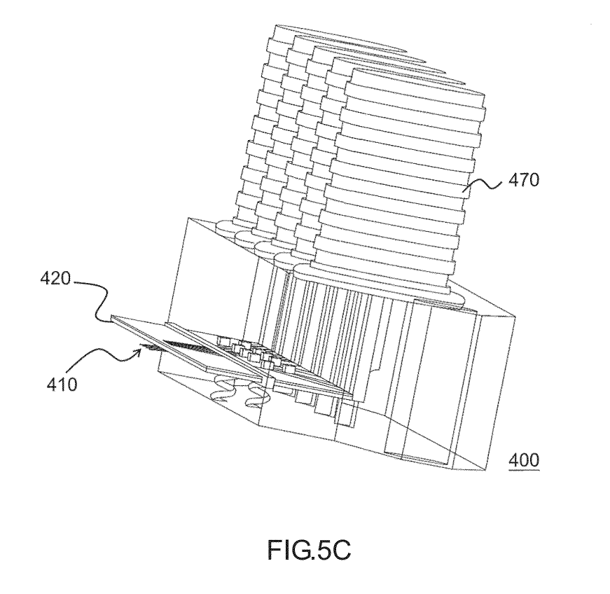

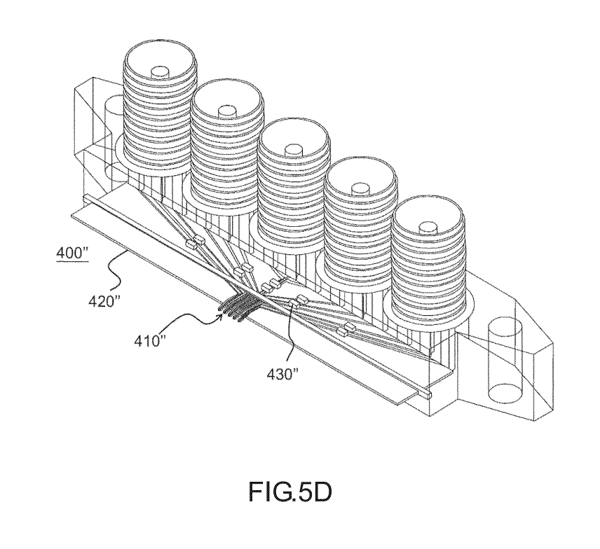

FIG. 5A through FIG. 5D are structural schematic views of a probe card according to the third embodiment of the present invention. FIG. 5A is a top view of the probe card. FIG. 5B is a top view of the probe card with a circuit module. FIG. 5C is a right perspective view of FIG. 5B. Referring to FIG. 5A through FIG. 5C, as regards a probe card 400 in the third embodiment, a plurality of probe modules 410 is disposed on a first carrier board 420. The first carrier board 420 is at least partially transparent and is an oblong carrier board. In particular, a plurality of probe modules 410 is coupled to the front end of the first carrier board 420, whereas a plurality of SMA connectors 470 is connected to the rear end of the first carrier board 420. Due to the plurality of probe modules 410, a plurality of devices under test can be concurrently measured with the probe card 400.

Referring to FIG. 5B, in a situation similar to the second embodiment, conducting wires 421a, 421b, 421c are connected to terminals 471a, 471b, 471c of the SMA connectors 470, respectively.

It is also feasible that the probe module 410″ and a circuit module 430″ of the probe card 400″ are positioned on the same side of the first carrier board 420″ (as shown in FIG. 5D) in the same way as described in the second embodiment.

The advantages of the probe cards 400, 400″ in the third embodiment are identical to that in the first embodiment and thus are not reiterated for the sake of brevity.

### Fourth Embodiment

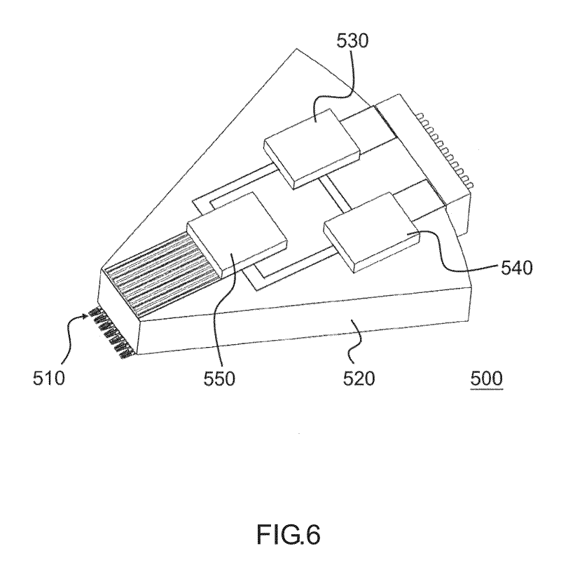

FIG. 6 is a structural schematic view of a probe card according to the fourth embodiment of the present invention. Referring to FIG. 6, regarding a probe card 500 in the fourth embodiment, not only is a probe module 510 disposed on a first carrier board 520, but a microcontroller module 530, a high-frequency circuit module 540, and a wave detector circuit module 550 which are opposite to the probe module 510 are disposed on the first carrier board 520, so as to enable the probe card 500 to send a signal and read a feedback signal when measuring the devices under test. The probe card 500 in the fourth embodiment has the same advantages as its counterpart in the first embodiment and thus are not reiterated for the sake of brevity.

Although the probes of the probe card in the first through fourth embodiments are arranged in a regular array and are made of a nickel-cobalt alloy, the first carrier boards are made of glass, whereas the conductive fillers are made of copper. But in the other embodiment, the probes are irregularly arranged, and the probes are made of carbon, carbon alloy, a single metallic material, or any other appropriate alloy. Furthermore, the first carrier boards may also be made of quartz or any other appropriate material which light can penetrate, whereas the conductive fillers may also be made of nickel, chromium, or any other appropriate material.

In conclusion, the probe card of the present invention at least has the following advantages:

1. Regarding the probe card put forth by the present invention, the first carrier board is at least partially light-transmitted. When the registration process is underway, an inspector watches from above the probe card the registration of the probe card and a device under test, and thus it is not necessary to take pictures of the probes or the device under test with a camera beforehand, nor is it necessary to compare repeatedly with a computer the pictures thus taken. In this regards, the present invention simply requires the user to move the probe card or the device under test directly to an appropriate location, thereby speeding up the registration procedure greatly. Furthermore, the inspector can observe synchronously and determine whether the contact between the probe card and the device under test is good, so as to ensure that the subsequent test steps can be performed successfully.

2. As regards the probe card of the present invention, the first carrier board is at least partially light-transmitted such that, to perform measurement, it is feasible to irradiate an optical component or a photoelectrical component on the device under test in order to apply an additional signal.

3. In the first embodiment of the present invention, the first carrier board is a glass substrate, and signal return loss is reduced by means of the insulation characteristic of a glass substrate having therein a plurality of through glass vias (TGV).

4. A probe card manufacturing method of the present invention involves processing the probes by a planarization process, and thus coplanarity of the probes is satisfactory, thereby reducing the likelihood of unsatisfactory contact between the probes and the device under test.

Although the present invention is disclosed and illustrated with preferred embodiments, the preferred embodiments are not restrictive of the present invention. Persons skilled in art can make some changes and modifications to the preferred embodiments without departing from the spirit and scope of the present invention. Accordingly, the legal protection for the present invention is defined by the appended claims.

What is claimed is:

1. A probe card, comprising:
a probe module having a plurality of probes; and
a first carrier board being at least partially light-transmitted and having a plurality of vias and a plurality of conductive fillers, the vias being filled with the conductive fillers, respectively, wherein the probe module is disposed on the first carrier board and electrically connected to the conductive fillers.

2. The probe card of claim 1, further comprising a circuit module disposed on the first carrier board and electrically connected to the probe module through the conductive fillers.

3. The probe card of claim 2, further comprising a bonding pad redistribution layer disposed on the first carrier board and electrically connected to the conductive fillers.

4. The probe card of claim 2, wherein the circuit module comprises a microcontroller.

5. The probe card of claim 1, wherein the first carrier board is made of glass or quartz.

6. The probe card of claim 1, wherein the probes are arranged in an array.

7. The probe card of claim 1, wherein the probes are made of a metal or an alloy.

8. The probe card of claim 1, wherein the probes are made of carbon, a carbon compound, or a carbon alloy.

9. A probe card manufacturing method, comprising the steps of:
providing a first carrier board being at least partially light-transmitted and having thereon a plurality of vias, and filling the vias with a plurality of conductive fillers, respectively;
forming a plurality of bumps on the conductive fillers;
providing a second carrier board;
forming a plurality of needle-point cavities on the second carrier board by a photolithography process and an etching process;
forming a plurality of probes on the needle-point cavities by an electroforming process and a planarization process; and
coupling the probes to the bumps.

10. The probe card manufacturing method of claim 9, wherein the first carrier board is made of glass or quartz.

11. The probe card manufacturing method of claim 9, wherein the probes are made of a metal or an alloy.

12. The probe card manufacturing method of claim 9, wherein the probes are made of carbon, a carbon compound, or a carbon alloy.

13. The probe card manufacturing method of claim 9, further comprising the step of forming a bonding pad redistribution layer on the first carrier board and coupling a circuit module to the bonding pad redistribution layer.
